(19) United States
(12) Patent Application Publication
(10) Pub. No.: US 2011/0254042 A1
(43) Pub. Date: Oct. 20, 2011

(54) ELONGATED LENSES FOR USE IN LIGHT EMITTING APPARATUSES

(75) Inventor: ALEXANDER SHAIKEVITCH, Livermore, CA (US)

(73) Assignee: BRIDGELUX INC, LIVERMORE, CA (US)

(21) Appl. No.: 13/171,321

(22) Filed: Jun. 28, 2011

(51) Int. Cl. H01L 33/50; H01L 33/52; H01L 33/60

(52) U.S. Cl. 257/98; 257/E33.061; 257/E33.059; 257/E33.072; 257/E33.073

(57) ABSTRACT

A light emitting apparatus includes one or more light emitting semiconductors, and an elongated lens encapsulating the one or more light emitting semiconductors. The elongated lens comprises an exterior surface having a photoluminescent material thereon.

### BACKGROUND

1. Field

The present disclosure relates to light emitting apparatuses, and more particularly to elongated lenses for light emitting apparatuses and methods of manufacture of such lenses and devices.

2. Background

Light emitting semiconductors, such as light emitting diodes (LEDs), are attractive candidates for replacing conventional light sources such as incandescent and fluorescent lamps. LEDs have substantially higher light conversion efficiencies than incandescent lamps, and longer lifetimes than both types of conventional light sources. In addition, some types of LEDs now have higher conversion efficiencies than fluorescent light sources and still higher conversion efficiencies have been demonstrated in the laboratory. Finally, LEDs require lower voltages than fluorescent lamps, and therefore, provide various power saving benefits.

LEDs produce light in a relatively narrow spectrum band. In order to provide a suitable replacement for conventional light sources, LED light sources should produce white light. A white light source may be constructed from a blue LED in combination with photoluminescent material, such as phosphor. The blue light from the LED excites the phosphor at a high energy, which results in a portion of the blue light being converted to lower energy yellow light. The ratio of blue to yellow light may be chosen such that the LED light source appears to be white.

These types of light sources present technical challenges in terms of light extraction. Absorption by the medium may prevent light from reaching the surface of the LED. Light reaching the surface of the LED may be internally reflected because critical angles at the LED surface are typically small due to a large index of refraction mismatch between the LED and the surrounding medium.

Arranging the phosphor remote from the LED can reduce absorption and increase light extraction. Remote phosphor also improves the color stability by lowering the surface temperature of phosphor. However, the spatial color distribution of remote phosphor may be poor. Moreover, the uniformity of light may be low and a visible yellow ring may be generated.

Applying a phosphor layer to a clear convex lens encapsulating one or more LEDs is an attractive solution. Spatial color distribution can be improved and higher lumen output can be achieved. However, this process is difficult to realize. The flow of phosphor may generate a layer having a non-uniform thickness and the deposition of the phosphor particles on the surface of the convex lens may not adhere well.

### SUMMARY

In one aspect of the disclosure, a light emitting apparatus includes an elongated lens extending from a base along an elongated axis to an end of the lens, wherein the lens further comprises an exterior surface having a photoluminescent material thereon, and one or more light emitting semiconductors in the base of the lens.

In another aspect of the disclosure, a light emitting apparatus includes one or more light emitting semiconductors, and an elongated lens encapsulating the one or more light emitting semiconductors, wherein the lens comprises an exterior surface having a photoluminescent material thereon.

In a further aspect of the disclosure, a light emitting apparatus includes one or more light emitting semiconductors, and an elongated lens configured to support a photolumunescent material remote from the one or more light emitting semiconductors and in the pathway of light emitted from the one or more light emitting semiconductors.

It is understood that other aspects of the present invention will become readily apparent to those skilled in the art from the following detailed description, wherein it is shown and described only exemplary configurations of lenses, light emitting apparatuses, and methods for manufacture. As will be realized, the present invention includes other and different aspects of lenses, light emitting apparatuses, and methods of manufacture and its several details are capable of modification in various other respects, all without departing from the spirit and scope of the present invention. Accordingly, the drawings and the detailed description are to be regarded as illustrative in nature and not as restrictive.

### BRIEF DESCRIPTION OF THE FIGURES

Various aspects of the present invention are illustrated by way of example, and not by way of limitation, in the accompanying drawings, wherein:

FIG. 1 is a conceptual cross-sectional view illustrating an example of an LED;

FIG. 2 is a conceptual cross-sectional view illustrating an example of a light emitting apparatus with an elongated lens;

FIG. 3 is a conceptual cross-sectional view illustrating an example of a light emitting apparatus with an elongated lens and reflector;

FIG. 4 is a conceptual flow diagram illustrating the steps of a first manufacturing process for a light emitting apparatus with an elongated lens; and

FIG. 5 is a conceptual flow diagram illustrating the steps of a second manufacturing process for a light emitting apparatus with an elongated lens.

### DETAILED DESCRIPTION

The present invention is described more fully hereinafter with reference to the accompanying drawings, in which various aspects of the present invention are shown. This invention, however, may be embodied in many different forms and should not be construed as limited to the various aspects of the present invention presented throughout this disclosure. Rather, these aspects are provided so that this disclosure will be thorough and complete, and will fully convey the scope of the present invention to those skilled in the art. The various aspects of the present invention illustrated in the drawings may not be drawn to scale. Rather, the dimensions of the various features may be expanded or reduced for clarity. In addition, some of the drawings may be simplified for clarity. Thus, the drawings may not depict all of the components of a given apparatus or method.

Various aspects of the present invention will be described herein with reference to drawings that are schematic illustrations of idealized configurations of the present invention. As such, variations from the shapes of the illustrations as a result, for example, manufacturing techniques and/or tolerances, are to be expected. Thus, the various aspects of the present invention presented throughout this disclosure should not be construed as limited to the particular shapes of elements (e.g., regions, layers, sections, substrates, bulb shapes, etc.) illustrated and described herein but are to include deviations in shapes that result, for example, from manufacturing. By way of example, an element illustrated or described as a rectangle may have rounded or curved features and/or a gradient concentration at its edges rather than a discrete change from one element to another. Thus, the elements illustrated in the drawings are schematic in nature and their shapes are not intended to illustrate the precise shape of an element and are not intended to limit the scope of the present invention.

It will be understood that when an element such as a region, layer, section, substrate, or the like, is referred to as being “on” another element, it can be directly on the other element or intervening elements may also be present. In contrast, when an element is referred to as being “directly on” another element, there are no intervening elements present. It will be further understood that when an element is referred to as being “formed” on another element, it can be grown, deposited, etched, attached, connected, coupled, or otherwise prepared or fabricated on the other element or an intervening element.

Furthermore, relative terms, such as “lower” or “bottom” and “upper” or “top,” may be used herein to describe one element's relationship to another element as illustrated in the drawings. It will be understood that relative terms are intended to encompass different orientations of an apparatus in addition to the orientation depicted in the drawings. By way of example, if an apparatus in the drawings is turned over, elements described as being on the “lower” side of other elements would then be oriented on the “upper” side of the other elements. The term “lower”, can therefore, encompass both an orientation of “lower” and “upper,” depending of the particular orientation of the apparatus. Similarly, if an apparatus in the drawing is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this disclosure.

As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. The term “and/or” includes any and all combinations of one or more of the associated listed items.

Various aspects of light emitting apparatuses, lenses for light emitting apparatuses, methods for manufacturing will now be presented. However, as those skilled in the art will readily appreciate, these aspects may be extended to other apparatuses, lenses, and manufacturing processes without departing from the scope of the invention. Various configurations of the light emitting apparatuses presented throughout this disclosure may provide a direct replacement for conventional light sources, including, by way of example, incandescent, fluorescent, halogen, quartz, high-density discharge (HID), and neon lamps or bulbs. The light emitting apparatuses may use light emitting semiconductors, such as a light emitting diodes (LED) or other components, as a light source. LEDs are well known light sources, and therefore, will only briefly be discussed to provide a complete description of the invention.

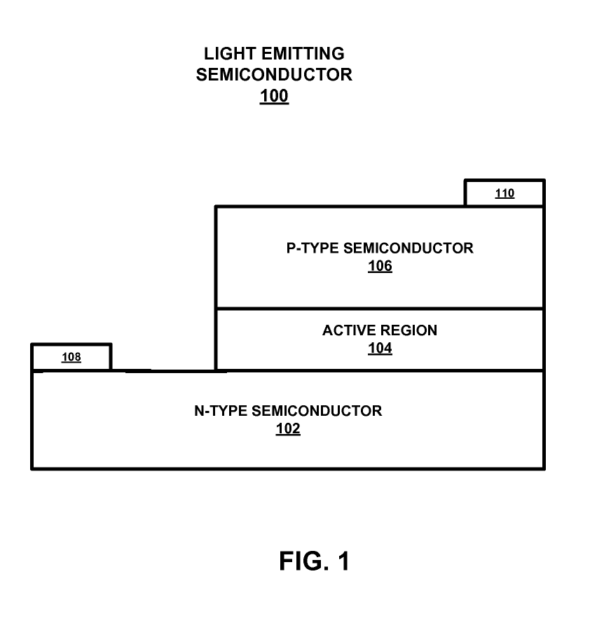

FIG. 1 is a conceptual cross-sectional view illustrating an example of an LED 100. An LED is a semiconductor material impregnated, or doped, with impurities. These impurities add “electrons” and “holes” to the semiconductor, which can move in the material relatively freely. Depending on the kind of impurity, a doped region of the semiconductor can have predominantly electrons or holes, and is referred respectively as n-type or p-type semiconductor regions. Referring to FIG. 1, the LED 100 includes an n-type semiconductor region 102 and a p-type semiconductor region 106, although additional layers or regions (not shown) may be included in the LED 100, including but not limited to buffer, nucleation, contact and current spreading layers or regions, as well as light extraction layers. A reverse electric field is created at the junction between the two regions, which cause the electrons and holes to move away from the junction to form an active region 104. When a forward voltage sufficient to overcome the reverse electric field is applied across the PN junction through a pair of electrodes 108, 110, electrons and holes are forced into the active region 106 and recombine. When electrons recombine with holes, they fall to lower energy levels and release energy in the form of light.

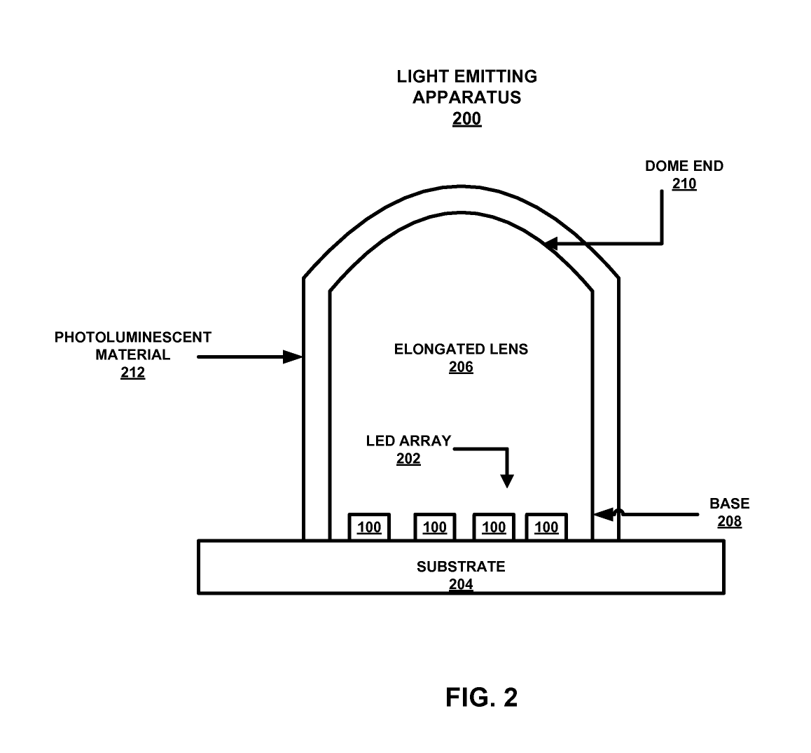

FIG. 2 is a conceptual cross-sectional view illustrating an example of a light emitting apparatus. The light emitting apparatus 200 is shown with a light source comprising an LED array 202. The LED array 202 may take on various forms. By way of example, the LED array may be constructed from a semiconductor LED wafer comprising bare, unpackaged LEDs or chips. These LED chips are also referred to as “dies.” Individual LED chips 100 may be affixed to a substrate 204 (e.g., printed circuit board) by means well known in the art. The resulting LED array 202 is sometimes referred to as a “chip-on-board” LED array. The pins or pads or actual surfaces of the LED chips 100 may be attached to conductive traces (not shown) on the substrate 204. These conductive traces connect the LED chips 100 in a parallel and/or series fashion. The printed circuit board 204 may be any suitable material that can provide support to the LED chips 100.

Various aspects of an elongated lens will now be presented in connection with the chip-on-board LED array shown in the light emitting apparatus of FIG. 2. However, as those skilled in the art will readily appreciate, these aspects may be extended to other light emitting semiconductor arrangements. More specifically, the various aspects of an elongated lens presented throughout this disclosure may be extended to any suitable arrangement of one or more light emitting semiconductors requiring a lens.

In the configuration shown in FIG. 2, the elongated lens 206 includes a base 208 containing the LED array 200. The elongated lens 206 is shown with a tubular portion that extends from the base 208 along an elongated axis to a dome shaped end 210, however, lens shapes may be used depending upon the specific application and the overall design constraints imposed on the apparatus. Such a lens may provide more light than a simple hemispherical lens when the light source is essentially a surface source and not a spot light source. As used herein, the term “elongated lens” means a lens wherein the normal axis to the substrate is the elongated axis. In a configuration of such an elongated lens, the ratio of the elongated dimension to the lateral dimension may be between 1.25 and 2.5. By way of example, in a configuration of the lens, the elongated axis may be between 10 and 20 mm and the lateral dimension is between 8-10 mm. Of course, other dimensions may be used and those skilled in the art will be readily able to determine the dimensions of the lens best suited for any particular application based on the teachings presented throughout this disclosure.

The elongated lens 206 may be formed from an encapsulation material, such as epoxy, silicone, or other suitable transparent material. In a configuration of an elongated lens 206, the encapsulation material comprises a layered structure where the refractive index of material is gradually or step-wise decreasing from the base 208 of the lens 206 towards the domed end 210. This configuration may increase light extraction and provide a more uniform distribution of emitted light. Introducing some light scattering non-absorbing particles like fumed alumina or silica selectively can also help to control light uniformity along the lens 206.

The elongated lens 206 may have a photoluminescent material 212 applied to its surface. The photoluminescent material 212 may be phosphor, phosphor particles deposited in a carrier (e.g., silicone), or any other suitable photoluminescent material. A non-limiting example of photoluminescent material comprises phosphor particles dispersed throughout a carrier such as silicone, epoxy, or other suitable material. The remote placement of the photoluminescent material may provide increased light extraction and lumen output while keeping the dimension of the light emitting apparatus 200 to a minimum. By way of example, this configuration may be used to support relatively large dies (e.g., 60×60 mil) in a small package having a working area of 300 mil occupying almost all of the area at the base of the lens, compared to conventional light sources where the LED array is designed to be at least 2.5 times smaller than the lateral dimension of the lens to provide best light extraction. The large surface area of the elongated lens 206 with a thin layer of photoluminescent material 212 may also provide efficient cooling of the material 212 by air convection making it as thermally stable as devices with conformal coating phosphor, where the heat is dissipated via a substrate and heat sink. This may enable use of conventional ceramic or printed circuit board substrates instead of metal (copper or aluminum), which are more compatible with other electronic components and allows more options in mounting and assembling. In a manner to be described in greater detail later, the photoluminescent material 212 may be applied to the elongated lens 206 with a thickness between 0.3 and 0.5 mm, or some other suitable thickness.

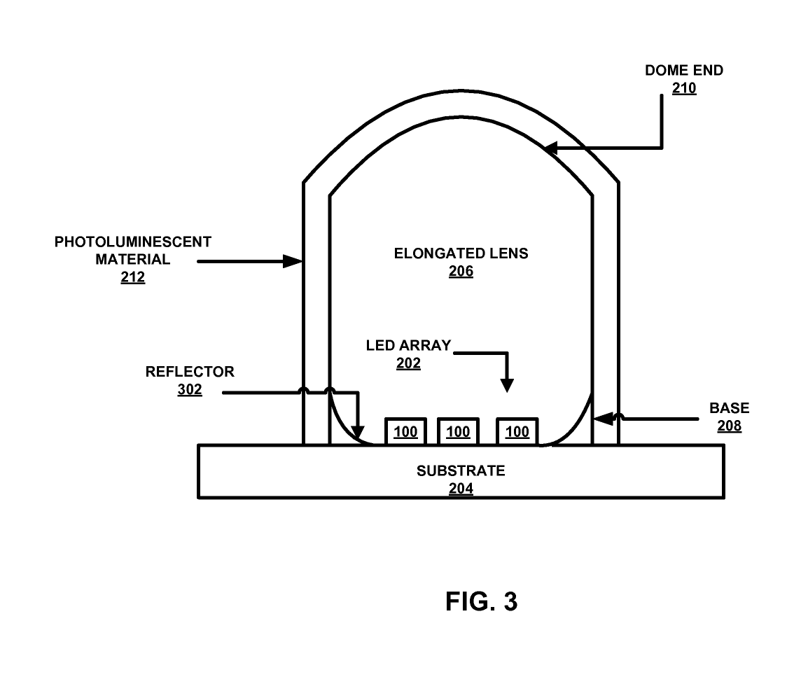

In a configuration of a light emitting apparatus 200, a reflector may be used to achieve a more uniform distribution of light. FIG. 3 is a conceptual cross-sectional view illustrating an example of a light emitting apparatus 200 with a reflector 302. In this configuration, the reflector 302 extends circumferentially around the LED array 202 at the base 208 of the elongated lens 206. The reflector 302 is shown having a cylindrical outer wall and a hyperbolic inner wall, but may be designed differently. In some configurations, multiple reflectors may be used instead of a single reflector. Those skilled in the art will be readily able to determine the optimal reflector design from the teachings herein depending upon the particular application and the overall design constraints imposed on the light emitting apparatus 200. In a configuration of a light emitting apparatus 200, a diffuse reflector may be used to scatter the light emitted from the LED array 202 at the base of the lens 206.

Various methods may be used to manufacture a light emitting apparatus with an elongated lens. These methods may be used to form an elongated lens and apply a photoluminescent material to the exterior surface of the lens. Two exemplary methods will be presented that provide a uniform layer of photoluminescent material on the elongated lens with good adhesion properties, however, as those skilled in the art will readily understand, other methods of manufacture may be used.

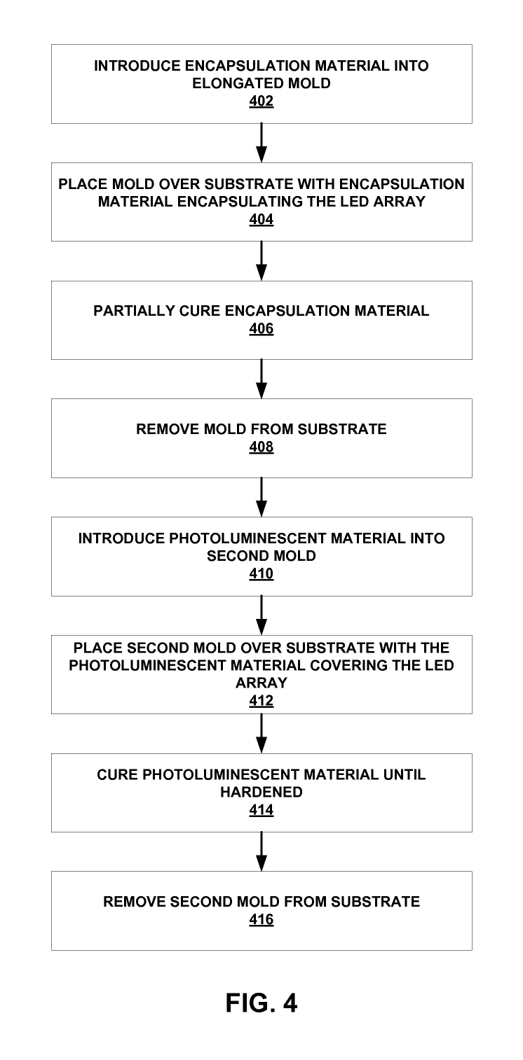

The first method is an over-molding process that will be presented with reference to FIG. 4. With this process, a clear silicone lens is created by over-molding the substrate populated with an array of LEDs. A suitable material, such as silicone, with strong adhesion properties may be used. The silicon may have the additional property of remaining tacky when partially cured. A non-limiting example of a silicone suitable for the over-molding process is KER2500 manufactured by Shin Etsu Chemical Co., Ltd.

Turning to FIG. 4, an encapsulation material, such as silicone, epoxy, or other suitable material, may be introduced into an elongated mold in step 402. In this example, the elongated mold has a tubular shape with a domed end, but the mold may have other shapes depending on the specific design of the lens. Once the encapsulation material is introduced into the mold, the mold is then placed over the substrate with the material encapsulating the LED array in step 404. Next, in step 406, the encapsulation material is partially cured until the material is firm but tacky. By way of example, in a process of manufacturing a lens using a KER2500 silicone material, the material may be partially cured by applying heat for 10-15 minutes. The time to fully cure this silicone material is 1-2 hours. Once the encapsulation material is partially cured, the mold is then removed in step 408, leaving a partially cured elongated lens encapsulating the LED array.

A photoluminescent material layer may then be applied to the partially cured encapsulation material using a second mold, which is 0.3 to 0.5 mm bigger in all dimensions than that one used for the lens. In step 410, sufficient photoluminescent material to cover the lens is introduced into the second mold. A non-limiting example of photoluminescent material comprises phosphor particles dispersed throughout a carrier such as silicone, epoxy, or other suitable material. In step 412, the second mold is then placed over the substrate with the photoluminescent material covering the lens. The photoluminescent material is cured until hardened in step 414. The second mold is then removed in step 416, leaving an elongated lens with a thin uniform coating of photoluminescent material.

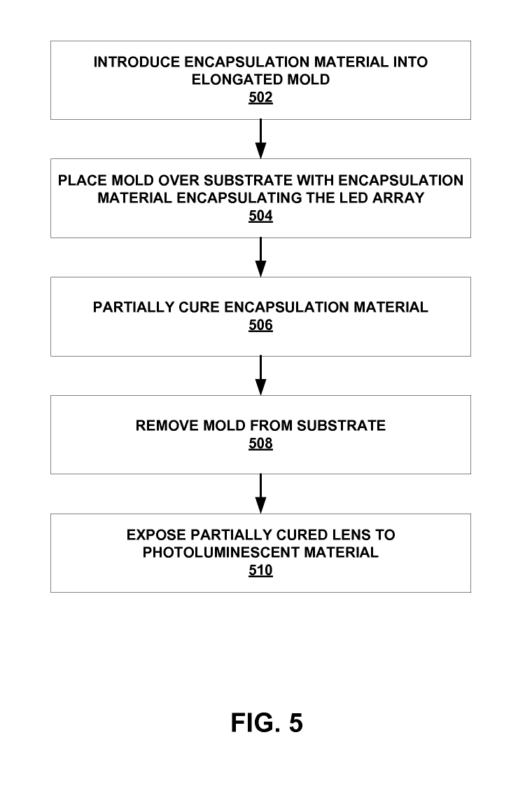

The second method is a coating process using a fluidized bed that will be presented with reference to FIG. 5. With this process, the elongated lens may be formed by the same process described earlier, or by other means. That is, an encapsulation material is introduced into an elongated mold in step 502. The mold is then placed over the substrate with the material encapsulating the LED array in step 504. Next, in step 506, the encapsulation material is partially cured until the material is firm but tacky. The mold is then removed in step 508, leaving a partially cured elongated lens encapsulating the LED array.

The partially cured lens may then be exposed to a photoluminescent material in step 510 using a fluidized bed or by other suitable means. By way of example, the partially cured lens may be exposed to flying phosphor particles in a fluidized bed. The flying particles stick to the tacky lens, thus creating a thin coating of photoluminescent material. This method generally provides a thinner layer of photoluminescent material which can be more effectively cooled by air convection and deliver more light due to the absence of internal reflections between the photoluminescent material and the encapsulation material. However, color control may be more difficult to achieve, especially when more than one phosphor is used to create photoluminescent layer.

The various aspects of this disclosure are provided to enable one of ordinary skill in the art to practice the present invention. Various modifications to aspects presented throughout this disclosure will be readily apparent to those skilled in the art, and the concepts disclosed herein may be extended to other light emitting apparatuses and lenses. Thus, the claims are not intended to be limited to the various aspects of this disclosure, but are to be accorded the full scope consistent with the language of the claims. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “step for.”

What is claimed is:

1. A light emitting apparatus, comprising:
an elongated lens extending from a base along an elongated axis to an end of the lens, wherein the lens further comprises an exterior surface having a photoluminescent material thereon; and
one or more light emitting semiconductors in the base of the lens.

2. The light emitting apparatus of claim 1 wherein the lens further comprises a tubular portion extending from the base to the end of the lens, and wherein the end of the lens is domed.

3. The light emitting apparatus of claim 1 wherein the lens comprises an interior portion having encapsulation material.

4. The light emitting apparatus of claim 3 wherein the encapsulation material comprises a plurality of layers including a first one of the layers having a first refractive index and a second one of the layers having a second refractive index, the first one of the layers being between the second one of the layers and the base of the lens, and wherein the first refractive index is less than the second refractive index.

5. The light emitting apparatus of claim 3 wherein the encapsulation material includes a plurality of light scattering particles.

6. The light emitting apparatus of claim 1 further comprising one or more reflectors in the base of the lens and arranged with the one or more light emitting semiconductors.

7. The light emitting apparatus of claim 6 wherein the one or more reflectors comprise one or more diffuse reflectors.

8. A light emitting apparatus, comprising:
one or more light emitting semiconductors; and
an elongated lens encapsulating the one or more light emitting semiconductors, wherein the lens comprises an exterior surface having a photoluminescent material thereon.

9. The light emitting apparatus of claim 8 wherein the lens extends from a base along an elongated axis to an end of the lens, the one or more light emitting semiconductors being in the base of the lens.

10. The light emitting apparatus of claim 9 wherein the lens further comprises a tubular portion extending from the base to the end of the lens, and wherein the end of the lens is domed.

11. The light emitting apparatus of claim 8 wherein the lens comprises an encapsulation material comprising a plurality of layers including a first one of the layers having a first refractive index and a second one of the layers having a second refractive index, the first one of the layers being between the second one of the layers and the base of the lens, and wherein the first refractive index is less than the second refractive index.

12. The light emitting apparatus of claim 8 wherein the lens comprises an interior portion having encapsulation material including a plurality of light scattering particles.

13. The light emitting apparatus of claim 8 further comprising one or more reflectors encapsulated by the lens and arranged with the one or more light emitting semiconductors.

14. The light emitting apparatus of claim 13 wherein the one or more reflectors comprise one or more diffuse reflectors.

15. A light emitting apparatus, comprising:
one or more light emitting semiconductors; and
an elongated lens configured to support a photolumunescent material remote from the one or more light emitting semiconductors and in the pathway of light emitted from the one or more light emitting semiconductors.

16. The light emitting apparatus of claim 15 wherein the lens extends from a base along an elongated axis to an end of the lens, the one or more light emitting semiconductors being in the base of the lens.

17. The light emitting apparatus of claim 16 wherein the lens further comprises a tubular portion extending from the base to the end of the lens, and wherein the end is domed.

18. The light emitting apparatus of claim 15 wherein the lens comprises an interior portion having an encapsulation material.

19. The light emitting apparatus of claim 18 wherein the encapsulation material comprises a plurality of layers having a first one of the layers having a first refractive index and a second one of the layers having a second refractive index, the first one of the layers being between the second one of the layers and the base of the lens, and wherein the first refractive index is less than the second refractive index.

20. The light emitting apparatus of claim 15 further comprising one or more reflectors arranged with the one or more light emitting semiconductors to reflect a portion of the light emitted by the one or more light emitting semiconductors to the remote photoluminescent material.
